(19) United States
(12) Patent Application Publication
(10) Pub. No.: US 2019/0373768 A1
(43) Pub. Date: Dec. 5, 2019

(54) ELECTRONICS COLD PLATE

(71) Applicant: Hanon Systems, Daejeon (KR)

(72) Inventors: Evangelos S. Papoulis, Northville, MI (US); Kenneth Belford, Pinckney, MI (US); Daniel Lumley, Novi, MI (US)

(21) Appl. No.: 16/117,476

(22) Filed: Aug. 30, 2018

Related U.S. Application Data
(60) Provisional application No. 62/678,687, filed on May 31, 2018.

(51) Int. Cl. H05K 7/20

(52) U.S. Cl. CPC H05K 7/20254; H05K 7/20272

(57) ABSTRACT

A cold plate assembly includes a cold plate block having a first surface and a second surface opposite the first surface. The cold plate block is configured to mount a heat source thereto. A channel is formed in the first surface of the cold plate block. A cover plate covers the channel. A thermal interface material layer is disposed on the cover plate.

### CROSS-REFERENCE TO RELATED

This patent application claims the benefit of U.S. Provisional Patent Application Ser. No. 62/678,687 filed on May 31, 2018. The entire disclosure of the above patent application is hereby incorporated herein by reference.

### FIELD OF INVENTION

This disclosure relates generally to a cold plate assembly for thermal management of a heat source and, more particularly, to a cold plate assembly for thermal management of electronic devices, wherein the cold plate assembly includes a cold block defining a cooling channel therein and a cover plate covering the cooling channel.

### FIELD OF INVENTION

As known, solid-state electronic devices, such as electronic components in vehicles, generate heat during operation thereof. The heat generated, if significant enough, can damage the electronic devices resulting in a loss of performance of the electronic devices or actual physical damage to the electronic devices. It is commonly desired to minimize a size of the electronic devices depending on package requirements. However, as the size of the electronic devices are minimized, the heat generated by the device during operation at higher electrical power usage becomes more of a concern. Therefore, it is desired to efficiently cool the electronic devices to avoid damage.

Solid-state electronic devices often employ a thermal interface such as a heat sink or a cold plate that draws heat away from, and thus cools, the electronic devices during operation of the electronic devices. Often, the heat sink relies on a flow of air around the heat sink and the electronic device to help minimize the temperature of the electronic devices. Known machined cold plates often employ a thermal interface material (TIM) on a top surface of the cold plate. However, the cold plates typically have an uneven top surface. The TIM on the uneven top surface of the cold plate causes small gaps to form between the TIM and the cold plate. As a result of the gaps, the efficiency of the heat transfer between the electronic device and the cold plate is minimized. Thus, known cold plates with TIM typically do not allow for optimal or direct contact between the electronic device and the cold plate which results in inefficient and undesirable cooling of the electronic devices.

Therefore, it is desired to have a cold plate configured for direct mounting to a heat source such as an electronic device, wherein the cold plate maximizes an efficiency of cooling the heat source and a complexity of manufacturing the cold plate is minimized.

### SUMMARY

In accordance and attuned with the present invention, a cold plate configured for direct mounting to a heat source such as an electronic device, wherein the cold plate maximizes an efficiency of cooling the heat source and a complexity of manufacturing the cold plate is minimized has surprisingly been discovered.

Additional features of the disclosure will become apparent from the following description and appended claims, taken in conjunction with the accompanying drawings.

### BRIEF DESCRIPTION OF THE DRAWINGS

The above objects and advantages of the invention, as well as others, will become readily apparent to those skilled in the art from reading the following detailed description of an embodiment of the invention when considered in the light of the accompanying drawings, in which:

FIG. 1 is a cross-sectional elevational view of a heat source cooling assembly according to an embodiment of the disclosure;

FIG. 2 is an assembled top perspective view of a heat source cooling assembly according to another embodiment of the disclosure; and

FIG. 3 is a partially exploded top perspective view of the heat source cooling assembly shown in FIG. 2.

### DETAILED DESCRIPTION OF THE EMBODIMENTS

The following detailed description and appended drawings describe and illustrate various exemplary embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical unless otherwise noted.

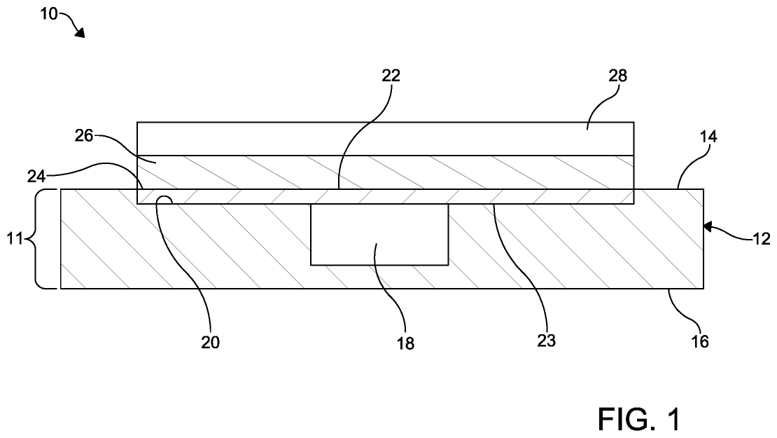

FIG. 1 shows a heat source cooling assembly 10 including a heat source 28 under thermal management and a cold plate assembly 11. The heat source 28 is configured as an electronic device such as a solid-state electronic device for an autonomous vehicle. Although it is understood the heat source 28 can be any electronic device for any vehicle or for any other application. Additionally, the heat source 28 can be any device or component requiring cooling or thermal management. The cold plate assembly 11 is directly mounted to the heat source 28 and configured to transfer heat from the heat source 28 to the cold plate assembly 11.

The cold plate assembly 11 includes a cold plate block 12. For example, the cold plate block 12 is an aluminum block. Although it is understood the cold plate block 12 can be formed from any material with a high thermal conductivity such as a copper material, an aluminum alloy material, a gold material, an iron material, or any other material, as desired. The cold plate block 12 has a first surface 14 and a second surface 16 opposite the first surface 14. The first surface 14 faces the heat source 28 and is substantially planar except for portions described herein below such as a cooling channel 18 and a groove 20. As used herein, “substantially” means “to a considerable degree,” “largely,” or “proximately” as a person skilled in the art in view of the instant disclosure would understand the term. In the embodiment illustrated, the cold plate block 12 has a substantially rectangular cross-sectional shape. However, the cold plate block 12 can have any cross-sectional shape, as desired such as circular, polygonal, ovular, a combination thereof, or any other shape.

The cold plate block 12 defines the cooling channel 18. The cooling channel 18 may be formed in the first surface 14 by a machining process or other process. The cooling channel 18 conveys a cooling fluid there through. The cooling fluid can be a glycol, for example. Although, other cooling fluids can be employed such as a coolant, water, or a refrigerant, for example. The cooling fluid is conveyed to the cooling channel 18 of the cold plate block 12 from a cooling fluid source (not shown). The cooling channel 18 can extend linearly from one end of the cold plate block 12 to an opposing end of the cold plate block 12. However, in other embodiments, the cooling channel 18 can extend in an arcuate, serpentine, angled, or other manner from the one end of the cold plate block 12 to the opposing end of the cold plate block 12. Additionally, the cooling channel 18 can extend from any end or side and return to the same end or side or to an adjacent end or side. The groove 20 is formed into the first surface 14 along a perimeter or an edge of the cooling channel 18. As shown, the groove 20 has a depth less than a depth of the cooling channel 18.

The cold plate assembly 11 further includes a stamped cover plate 24 with an outer surface 22 and an inner surface 23 opposite the outer surface 22, although other processes can be used to form the cover plate 24 as desired. The cover plate 24 can be an aluminum plate. However, other materials can be employed to form the cover plate 24, as desired, such as materials with a high thermal conductivity. The cover plate 24 is configured to fit within the groove 20 and cover the cooling channel 18. The cover plate 24 has a thickness substantially equal to the depth of the groove 20, wherein the outer surface 22 of the cover plate 24 is substantially flush or substantially constant with the first surface 14 of the cold plate block 12. The cover plate 24 is brazed to the cold plate block 12 in a suitable oven by using a clad brazing material (not shown) that melts under heat to join the cover plate 24 and the cold plate block 12. The brazing results in a thermal joint providing the desired thermal contact between the cover plate 24 and the cold plate block 12. The brazing occurs between the cover plate 24 and the cold plate block 12 at the groove 20 and an outer perimeter of the inner surface 23 of the cover plate 24 aligning with the groove 20. A surface area of the outer surface 22 of the cover plate 24 is advantageously equal to a surface area of a surface of the heat source 28 contacting the cover plate 24. Although, it is understood the surface area of the outer surface 22 of the cover plate 24 can be greater than the surface area of the surface of the heat source 28 contacting the cover plate 24.

A thermal interface material (TIM) layer 26 is disposed between the heat source 28 and the cover plate 24. The TIM layer 26 can be any thermal interface material now known or later developed providing efficient thermal communication between the heat source 28 and the cover plate 24. For example, the TIM layer 26 can be a suitable plastic, a grease, an epoxy, a phase change material, a polymide tape, a graphite tape, an aluminum tape, a silicon coated material, a thermal paste, a gap filler, a combination thereof, or any other suitable TIM as desired. The TIM layer 26 is in complete contact with the outer surface 22 of the cover plate 24 and does not extend beyond edges of the cover plate 24. The heats source 28 is in complete contact with the TIM layer 26. The cooling fluid flows through the cooling channel 18 and transfers heat generated by the heat source 28 through the TIM layer 26 and the cover plate 24.

To assemble the heat source cooling assembly 10, after separately machining the cold plate block 12 and the cover plate 24, the cover plate 24 is received in the groove 20 and is brazed to the cold plate block 12 to cover the cooling channel 18. The TIM layer 26 is disposed on the cover plate 24. The cooling channel 18 is positioned in fluid communication with the fluid source via an inlet and an outlet (not shown). The heat source 28 is mounted directly to the TIM layer 26 and cover plate 24 by mounting means.

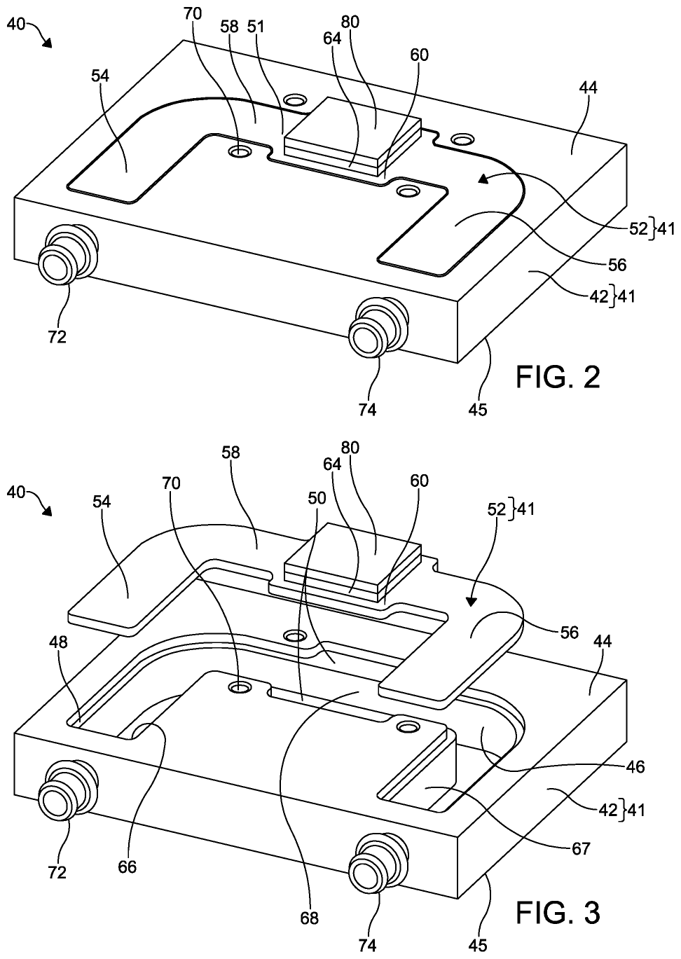

FIGS. 2-3 show a heat source cooling assembly 40 according to another embodiment of the disclosure. The heat source cooling assembly 40 is substantially similar to the heat source cooling assembly 10 of FIG. 1 but with a substantially U-shaped cooling channel 26 and a substantially U-stamped shaped cover plate 52.

The heat source cooling assembly 40 includes a heat source 80 under thermal management and a cold plate assembly 41. The heat source 80 is configured as an electronic device such as a solid-state electronic device for an autonomous vehicle. Although, it is understood, the heat source 80 can be any electronic device for any vehicle or for any other application. Additionally, the heat source 80 can be any device or component requiring cooling or thermal management. The cold plate assembly 41 is directly mounted to the heat source 80 and configured to transfer heat from the heat source 80 to the cold plate assembly 41.

The cold plate assembly 41 includes a cold plate block 42. For example, the cold plate block 42 is an aluminum block. Although, it is understood the cold plate block 42 can be formed from any material with a high thermal conductivity such as a copper material, an aluminum alloy material, a gold material, an iron material, or any other material, as desired. The cold plate block 42 has a first surface 44 and a second surface 45 opposite the first surface 44. The first surface 44 faces the heat source 80 and is substantially planar. As used herein, “substantially” means “to a considerable degree,” “largely,” or “proximately” as a person skilled in the art in view of the instant disclosure would understand the term. In the embodiment illustrated, the cold plate block 42 has a substantially rectangular cross-sectional shape. However, the cold plate block 42 can have any cross-sectional shape, as desired such as circular, polygonal, ovular, a combination of shapes, or any other shape.

The cold plate block 42 defines the cooling channel 46. The cooling channel 46 is formed in the first surface 44 by a machining process. The cooling channel 46 conveys a cooling fluid there through. The cooling fluid can be a glycol, for example. Although, other cooling fluids can be employed such as a coolant, water, or refrigerant, for example. The cooling fluid is conveyed to and from the cooling channel 46 of the cold plate block 42 from a cooling fluid source (not shown) through a pair of cooling fluid connectors 72, 74. The cooling channel 46 is substantially U-shaped having leg portions 66, 67, and a base portion 68. A groove 48 is formed into the first surface 44 along an edge perimeter of the cooling channel 46. The groove 48 has a depth less than a depth of the cooling channel 46. The groove 48 has a widened area 50, wherein a width of the groove 48 at the widened area 50 is greater than a width of the groove 48 at a remaining area of the groove 48.

The cold plate assembly 41 further includes the cover plate 52 with an outer surface 51 and an inner surface 53 opposite the outer surface 51. The cover plate 52 can be an aluminum plate. However, other materials can be employed to form the cover plate 52, as desired, such as materials with high thermal conductivity. The cover plate 52 is configured to fit within the groove 48 and cover the cooling channel 46. The cover plate 52 has a thickness substantially equal to the depth of the groove 48, wherein the outer surface 51 of the cover plate 52 is substantially flush or substantially constant with the first surface 44 of the cold plate block 41. The cover plate 52 is brazed to the cold plate block 41 in a suitable oven by using a clad brazing material (not shown) that melts under heat to join the cover plate 52 and the cold plate block 42. The brazing results in a thermal joint providing the desired thermal contact between the cover plate 52 and the cold plate block 42. The brazing occurs between the cover plate 52 and the cold plate block 42 at the groove 48 and an outer perimeter of the inner surface 53 of the cover plate 52 aligning with the groove 48.

The cover plate 52 is substantially U-shaped including leg portions 54, 56 corresponding in shape to the leg portions 66, 67 of the cooling channel 46 and a base portion 58 corresponding in shape to the base portion 68 of the cooling channel 46. The base portion 68 of the cover plate 52 has a widened area 60 corresponding to the widened area 50 of the groove 48, wherein a width of the base portion 68 of the cover plate 52 at the widened area 60 is greater than a width of a remaining portion of the base portion 68 of the cover plate 52. A surface area of the outer surface 51 of the cover plate 52 at the widened area 60 is advantageously greater than a surface area of a surface of the heat source 80 contacting the cover plate 52. Although, it is understood the surface area of the outer surface 51 of the cover plate 52 at the widened area 60 can be substantially equal to the surface area of the surface of the heat source 80 contacting the cover plate 52.

A thermal interface material (TIM) layer 64 is disposed between the heat source 80 and the cover plate 52. In the embodiment illustrated, the TIM layer 64 is disposed between the widened area 60 of the base portion 58 of the cover plate 52 and the heat source 80. The TIM layer 64 can be any thermal interface material now known or later developed providing efficient thermal communication between the heat source 80 and the cover plate 52. For example, the TIM layer 64 can be a suitable plastic, a grease, an epoxy, a phase change material, a polymide tape, a graphite tape, an aluminum tape, a silicon coated material, a thermal paste, a gap filler, a combination thereof, or any other suitable TIM as desired. The TIM layer 64 is in complete contact with the cover plate 52 and does not extend beyond the edges of the cover plate 52. The heat source 80 is in complete contact with the TIM layer 64. The cooling fluid flows through the cooling channel 46 and draws away heat generated by the heat source 80 through the TIM layer 64 and the cover plate 52.

An array of four threaded mounting holes 70 is formed through the cold plate block 42 around and outside the widened area 60 of base portion 58 of the cover plate 52. The holes 70 are configured to provide a means for mounting the heat source 80 to the TIM layer 64 with a bracket or other structure (not shown). The holes 70 are close to the cover plate 52 but not abutting the cover plate 52. Since the cover plate 52 is recessed into the groove 48, clad material from brazing the cover plate 52 to the cold plate block 42 does not run into the holes 70 which could otherwise affect thermal performance of the cold plate assembly 41. It is understood more than or fewer than four holes can be formed in the cold plate block 42 as desired.

To assemble the heat source cooling assembly 40, after separately machining the cold plate block 42 and the cover plate 52, the cover plate 52 is received in the groove 48 and is brazed to the cold plate block 42 to cover the cooling channel 46. The holes 70 are formed through the cold plate block 42. The TIM layer 64 is disposed on the cover plate 52 in the widened area 60 of the base portion 58 of the cover plate 52. The cooling channel 46 is positioned in fluid communication with the fluid source via the cooling fluid connectors 72, 74. The heat source 80 is mounted directly to the TIM layer 64 and cover plate 52 by mounting means engaging and received by the holes 70.

Advantageously, the heat source cooling assembly 10, 40 of the present disclosure maximizes a cooling efficiency of the heat source 28, 80. Additionally, the cold plate assembly 11, 41 only includes two plate components, the cold plate block 12, 42 and the cover plate 24, 52 compared to prior art assemblies includes three or more plate components. The cold plate block 12, 42 is configured to allow mounting of the heat source 28, 80 directly to the cold plate assembly 11, 41. The smooth outer surface 22, 51 of cover plate 24, 52 being flush with the first surface 14, 44 of the cold plate block 12, 42 also allows the heat source 28, 80 to be directly mounted to the cold plate assembly 11, 41. As a result, the surface of the heat source 28, 80 contacting the cold plate assembly 11, 41 can directly engage evenly with cold plate assembly 11, 41, and directly to the TIM layer 26, 64, to maximize heat transfer between the heat source 28, 80 and the cold plate assembly 11, 41. The heat source cooling assembly 10, 40 of the present disclosure also minimizes leaks because and minimizes complexity of assembly and manufacturing.

The foregoing discussion discloses and describes merely exemplary embodiments of the present disclosure. One skilled in the art will readily recognize from such discussion and from the accompanying drawings and claims that various changes, modifications and variations can be made therein without departing from the spirit and scope of the disclosure as defined in the following claims.

What is claimed is:

1. A cold plate assembly comprising:
a cold plate block having a first surface and a second surface opposite the first surface, the cold plate block configured to mount a heat source thereto;
a channel formed in the first surface of the cold plate block;
a cover plate covering the channel; and
a thermal interface material layer disposed on the cover plate.

2. The cold plate assembly of claim 1, further comprising a groove formed in the first surface of the cold plate block along an edge of the channel.

3. The cold plate assembly of claim 2, wherein the groove includes a widened area, and wherein a width of the groove at the widened area is greater than a width of a remaining portion of the groove.

4. The cold plate assembly of claim 2, wherein the cover plate is received in the groove.

5. The cold plate assembly of claim 1, wherein the cold plate block is formed from a material with high thermal conductivity.

6. The cold plate assembly of claim 5, wherein the cold plate block is formed from an aluminum material.

7. The cold plate assembly of claim 1, wherein the cover plate has an outer surface and an inner surface, wherein the outer surface is substantially flush with the first surface of the cold plate block.

8. The cold plate assembly of claim 1, wherein the channel and the cover plate are substantially U-shaped.

9. The cold plate assembly of claim 1, wherein the channel receives a cooling fluid therein.

10. The cold plate assembly of claim 9, wherein the cooling fluid is a glycol.

11. The cold plate assembly of claim 1, wherein the cover plate is formed from a material with a high thermal conductivity.

12. The cold plate assembly of claim 11, wherein the cover plate is formed from an aluminum material.

13. The cold plate assembly of claim 1, wherein the cover plate is a stamped cover plate.

14. The cold plate assembly of claim 1, wherein a plurality of mounting holes is formed in the cold plate block exterior to the channel.

15. A cold plate assembly comprising:
a cold plate block having a first surface and a second surface opposite the first surface, the cold plate block configured to mount a heat source thereto;
a channel formed in the first surface of the cold plate block, the channel receiving a cooling fluid;
a groove formed along an edge of the channel;
a cover plate received in the groove and covering the channel, the cover plate flush with the first surface of the cold plate block; and
a thermal interface material layer disposed on the cover plate.

16. The cold plate assembly of claim 15, wherein the cold plate block and the cover plate are formed from an aluminum material, and wherein the cooling fluid is a glycol.

17. The cold plate assembly of claim 15, wherein the channel and the cover plate are substantially U-shaped.

18. The cold plate assembly of claim 17, wherein the groove has a widened area and the cover plate has a widened area configured for engaging the widened area of the groove.

19. The cold plate assembly of claim 18, wherein the thermal interface material is disposed on the widened area of the cover plate.

20. A heat source cooling assembly comprising:
a heat source;
a cold plate assembly directly engaging and exchanging heat with the heat source, the cold plate assembly further comprising:
a cold plate block having a first surface and a second surface opposite the first surface;
a channel formed in the first surface of the cold plate, the channel receiving a cooling fluid therein;
a cover plate covering the channel, the cover plate having an outer surface facing the heat source and an inner surface engaging the cold plate block, the outer surface of the cover plate flush with the first surface of the cold plate block, a surface area of the outer surface of the cover plate is one of equal to and greater than a surface area of a surface of the heat source engaging the cold plate assembly; and
a thermal interface material later disposed between the cover plate and the heat source.
